(19) United States
(12) Patent Application Publication
(10) Pub. No.: US 2013/0240822 A1
(43) Pub. Date: Sep. 19, 2013

(54) NONVOLATILE MEMORY DEVICE AND METHOD FOR MANUFACTURING THE SAME

(71) Applicant: Junichi WADA, Kanagawa-ken (JP)

(72) Inventor: Junichi WADA, Kanagawa-ken (JP)

(73) Assignee: KABUSHIKI KAISHA TOSHIBA, Tokyo (JP)

(21) Appl. No.: 13/607,464

(22) Filed: Sep. 7, 2012

(30) Foreign Application Priority Data
Mar. 16, 2012 (JP) 2012-061105

(51) Int. Cl. H01L 45/00

(52) U.S. Cl. CPC H01L 45/145; H01L 45/16
USPC 257/4; 257/2; 438/382

(57) ABSTRACT

A nonvolatile memory device includes a first film layer formed on a substrate, and a second film layer formed on the first film layer. The second film layer comprises a first oxide material having a first oxygen content, and a second oxide material disposed laterally of the first oxide material and having a second oxygen content that is greater than the first oxygen content. The memory device also includes a third film layer formed on the second film layer, and the third film layer is disposed on the first oxide material and exposes portions of the second oxide material.

### CROSS-REFERENCE TO RELATED APPLICATION

This application is based upon and claims the benefit of priority from Japanese Patent Application No. 2012-061105, filed Mar. 16, 2012; the entire contents of which are incorporated herein by reference.

### FIELD

Embodiments described herein relate to a nonvolatile memory device and a method for manufacturing the same.

### BACKGROUND

The resistance changing type nonvolatile memory device has drawn attention as the next generation nonvolatile memory device, owing to being scalable and being capable of increased capacity. The resistance changing type nonvolatile memory device is provided with plural memory cells (resistance changing elements). In the conventional memory cell, the first electrode, the resistance changing section, and the second electrode are stacked.

To form such a memory cell, a method has been considered in which a film is formed as a first electrode, a film is formed as a resistance changing section, and a film is formed as a second electrode are formed one atop the other in a stack, and the stacked films are subjected to various processes such as photolithographic methods and etching methods such as the RIE (Reactive Ion Etching) method to form isolated individual memory cells.

In the conventional resistance changing type nonvolatile memory device, capacity is increased by the stacking plural memory cells one atop the other. When the plural layer formation is carried out for the memory cell, the number of processes for film formation, light exposure, and etching processing in memory cell is increased, which increases manufacturing cost of the memory device. Further, in the conventional memory devices there exists undesirable reaction of etching gases with the materials used in the formation of the resistance changing section, which renders the etching processing difficult. Additionally, the resistance changing section of conventional memory devices are prone to current leakage, which results unreliable operation of the memory device.

Therefore, it is desirable to develop the nonvolatile memory device having a low cost and being excellent in mass productivity and a manufacturing method thereof.

### DESCRIPTION OF THE DRAWINGS

FIGS. 1A and 1B are schematic cross-sectional diagrams showing a memory cell of the nonvolatile memory device according to a first embodiment.

FIGS. 2A to 2C are schematic cross-sectional diagrams to explain the operation of the memory cell.

FIG. 3 is a schematic cross-sectional diagram showing a comparative example of a memory cell (PRIOR ART).

FIGS. 4A and 4B are schematic cross-sectional diagrams showing a memory cell of the nonvolatile memory device according to a second embodiment.

FIGS. 5A to 5H are schematic diagrams to explain the rectification characteristics of the second separation section.

FIGS. 6A to 6E are schematic cross-sectional diagrams to explain a method for the manufacture of the nonvolatile memory devices described herein.

### DETAILED DESCRIPTION

In general, according to one embodiment, an example will be given in regard to the implementation embodiments while referring to the FIGS. In the various diagrams, the same symbols are attached to the same constituent elements and the detailed explanation of common elements will be omitted for brevity.

According to the embodiment, there is provided a nonvolatile memory device having a reduced production cost while being highly capable of mass production, and a method of manufacturing the same.

The nonvolatile memory device related to the implementation embodiment is provided with plural memory cells having a first electrode layer, a variable resistance layer provided on top of the first electrode layer, and a second electrode layer provided on top of the variable resistance layer. The variable resistance layer comprises an oxide with an oxygen content that is less than the stoichiometric ratio of the oxide. The variable resistance layer may constitute an oxygen depleted region relative to other components adjoining the variable resistance layer thereby creating a region in the layer having holes, in other words, an electron depleted region or oxygen ion region. A first separation section is provided between the variable resistance layers of the adjacent memory cells. The first separation section contains an oxide having the same composition as the oxide contained in the variable resistance layer, however the oxygen content of the oxide contained in the first separation section is higher than the oxygen content of the oxide contained in the variable resistance layer and is stoichiometric so the separation layer does not have the region having holes. The absolute value of the standard Gibbs free energy of formation per oxygen atom to change the oxide material comprising the variable resistance layer into stoichiometric oxide is higher than the absolute value of the standard Gibbs free energy of formation per oxygen atom in the case of changing the second electrode into oxide.

In the nonvolatile memory device, the memory region for the formation of memory cells for the data memory and the peripheral circuit region for the formation of the peripheral circuit for driving the memory cells are provided. In this case, since the existing technology can be used appropriately in regard to the peripheral circuit region, the explanation in regard to the peripheral circuit region will be omitted. In the following, the examples will be given in regard to the memory region only.

The directional insets in the various diagrams represent three directions (X, Y, Z) that are perpendicular to each other.

### Embodiment 1

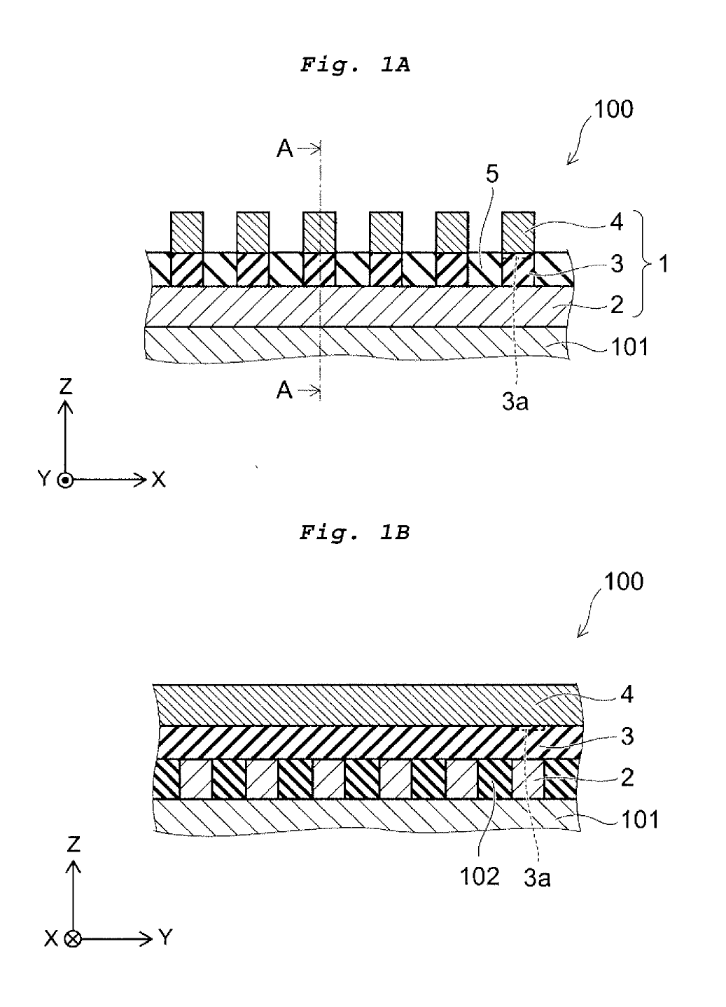

FIGS. 1A and 1B are schematic cross-sectional diagrams showing a memory cell 1 of a nonvolatile memory device 100 according to the first embodiment. FIG. 1B is the cross-sectional diagram of the section A-A in FIG. 1A.

As shown in FIGS. 1A, 1B, the memory cell 1 is provided with a first electrode 2, a variable resistance elements 3, and a second electrode 4.

The first electrode 2 is provided on top of a substrate 101 containing silicon.

First electrodes 2 are provided in specified intervals in the Y direction. The first electrode 2 comprises a linear form and is provided so that it extends in the X direction. The first electrode 2 is formed from an electrically conductive material. For example, the first electrode 2 can be formed from W, Ta, Cu or other metals, TiN, TaN, WC or other nitrides or carbides, as well as poly-silicon with the addition of a sufficient concentration of impurity elements (i.e., dopants).

The first electrode 2 can be made into, for example, a bit line. The plurality of first electrodes 2 are formed generally parallel to one another to provide bit lines for a memory array, and the individual first electrodes 2 are insulated from one another by an insulator 102. The insulator 102 can be formed of, for example, SiO₂ (silicon oxide) or the like.

The variable resistance elements 3 is provided on top of the first electrodes 2. The variable resistance elements 3 are formed from an oxide having an oxygen vs. metal element, such as silicon, content that is less than a stoichiometric ratio. Between individual elements 3 of the variable resistance layer are formed an insulating material 5 having the same chemical composition, but different stoichiometry than, the resistance changing elements.

The absolute value |ΔG₃| of the standard Gibbs free energy of formation ΔG₃ (kJ/mol, 298.15K) per oxygen atom in the case of changing the element contained in the resistance changing elements 3 to an oxide is larger than the absolute value |ΔG₄| of the standard Gibbs free energy of formation ΔG₄ per oxygen atom in the case of changing the element contained in the second electrode 4 to oxide.

For example, the absolute value of the standard Gibbs free energy of formation per oxygen atom in the case of changing the alloying or metal element, such as silicon, contained in the variable resistance elements 3 to an oxide is larger than the absolute value of the standard Gibbs free energy of formation per oxygen atom in the case of changing the alloying element, such as silicon contained in the second electrode 4 an to oxide.

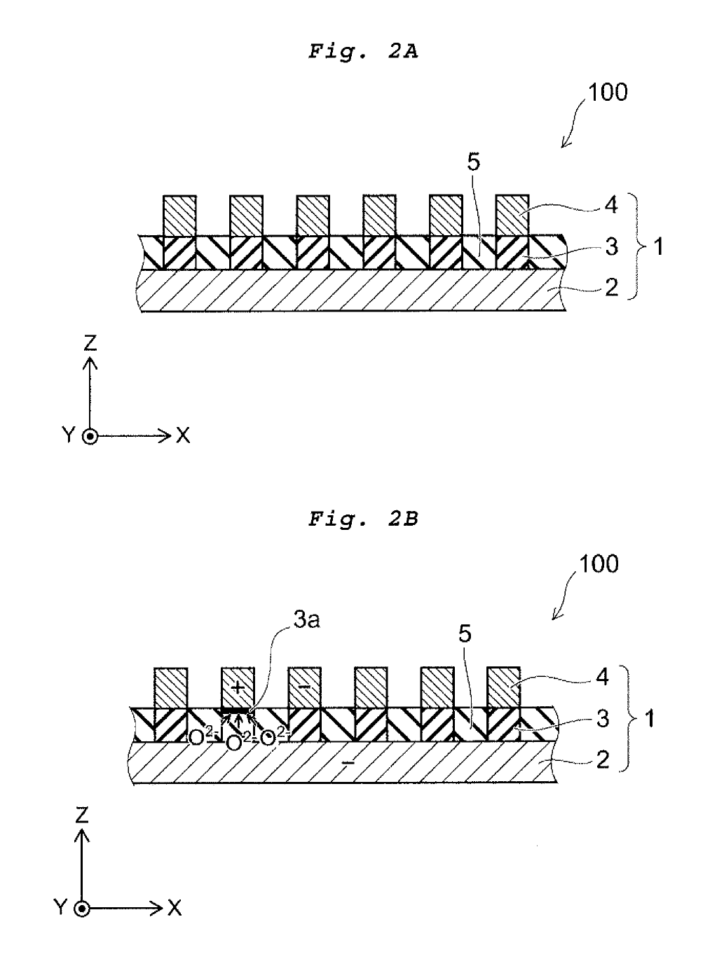

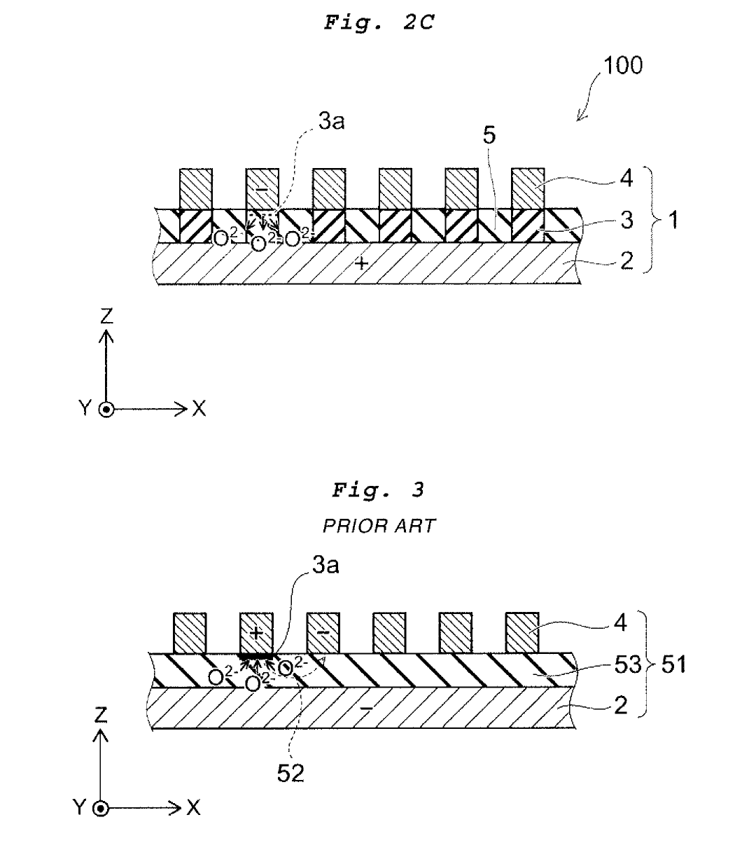

FIGS. 1A and 1B show the case in which the memory cell 1 is in the on state (the low resistance state). In this state, the ratio of oxygen to the alloying element, such as silicon, is sub-stoichiometric throughout the variable resistance layer, and the variable resistance layer is thus conductive. In the case in which the memory cell 1 is in the off state (the high resistance state), at the interface between the variable resistance elements 3 and the second electrode 4, an interface region 3a (shown in FIG. 2B) with a higher oxygen content than the remaining bulk of the variable resistance elements 3 is formed. As a result, the portion of the variable resistance element adjacent to the second electrode 4, which now has a higher oxygen content, approaches stoichiometry and the variable resistance layer becomes an insulator. The details in regard to the interface region 3a will be described later.

The second electrode 4 is provided over the variable resistance elements 3. The second electrode 4 is provided in registration to the underlying variable resistance elements at the same interval in the X direction as the interval of the resistance changing elements 3. The second electrode 4 comprises a linear form and is provided so that it extends in the Y direction. The second electrode 4 is formed of an electrically conductive material. The linear second electrode 4 can be formed as, for example, a word line in a memory array.

A first separation section 5 is provided between the variable resistance layers 3 of the memory cell 1. The first separation section 5 is provided on top of the first electrode 2. The first separation section 5 is provided between the variable resistance elements 3 in the X direction. The first separation section 5 spans adjacent memory cells 1. The first separation section 5 can be a material containing an oxide of the same alloying element, such as silicon in the case of silicon oxide, as the oxide contained in the variable resistance elements 3.

However, the oxygen content of the oxide contained in the first separation section 5 is higher than the oxygen content of the oxide contained in the variable resistance elements 3. Therefore, the first separation section 5 has a higher resistance than the variable resistance elements 3.

The variable resistance elements 3 and the first separation section 5 together comprise a linear shape and are provided so that they elongate in the Y direction. In this case, the position of the variable resistance elements 3 correspond to the position of the second electrodes 4.

The variable resistance elements 3 and the first separation section 5 are provided in one body and comprise a film form.

Next, an explanation will be given in regard to the variable resistance elements 3, the second electrode 4, and the first separation section 5.

The variable resistance elements 3 can be a material formed from an oxide containing, for example, Ti, Si, V, Ta, Mn, Nb, Cr, W, Mo, Fe or the like.

The second electrode 4 can be a material containing Al, Ti, Si, Ta, Mn, Nb, Cr, W, Mo, Fe, Co, Ni, Re, Cu, Ru, Ce, Ir, Pd, Ag or the like.

The materials of the variable resistance elements 3 and the second electrode 4 are not to be restricted to the examples, and an appropriate change can be made as long as the magnitude relationship of the absolute values of the standard Gibbs free energy of formation is satisfied to enable the resistance switching function of the resistance changing elements to occur without the escape of the oxygen ions from the resistance changing elements into the second electrodes 4. Thus, other than the magnitude relationship of the standard Gibbs free energy of formation, there are no special restrictions in the combination of materials for the variable resistance elements 3 and the second electrode 4.

In the case of a plural element type material containing plural elements, for example a three element oxide, it is acceptable that one of the elements of the plural elements satisfies the magnitude relationship of the absolute values of the standard Gibbs free energy of formation.

For example, in the case of the formation of the variable resistance elements 3 from NbOₓ (where x is less than 2.5), the second electrode 4 can be formed from Ru, Co, Ni, W or the like.

For example, in the case of the formation of the variable resistance elements 3 from TaOₓ (where x is less than 2.5), the second electrode 4 can be formed from Ru, Co, Ni, W, Nb or the like.

For example, in the case of the formation of the variable resistance elements 3 from WAlOₓ (where x is less than 2.5), the second electrode 4 can be formed from Ru, Co, Ni, or the like.

As described above, the oxygen content of the oxide contained in the first separation section 5 is stoichiometric, or closer to stoichiometry, than the oxygen content of the oxide contained in the variable resistance elements 3.

In this case, if the oxide compound contained in the first separation section 5 is the same as the oxide compound contained in the variable resistance elements 3, the oxygen content of the oxide compounds should be.

For example, when the first separation section 5 is formed from Nb₂O₅, the variable resistance elements 3 can be formed from NbOₓ (where x is less than 2.5).

Next, an example will be described in regard to the operation of the memory cell 1.

FIGS. 2A to 2C are schematic cross-sectional diagrams to describe operation of the memory cell 1.

FIG. 2A shows the memory cell 1 in the on state. In the on state, the resistance is minimal between the first electrode 2 and the second electrode 4. This is because, in the on state, the interface region 3a (shown in FIG. 2B) with a high oxygen content is not formed in the variable resistance elements 3 at a region between the first electrode 2 and the second electrode 4. The variable resistance elements 3 are in a state of oxidation (for example, a metal rich-metal oxide) with the oxygen content being less than the stoichiometric ratio. In this oxidation state, the variable resistance elements 3 are not a complete insulator, and the electric current of the specified electric current value can flow easily between the first electrode 2 and the second electrode 4.

FIG. 2B shows the case when the memory cell 1 is shifted from the on state to the off state. In the off state, there is increased resistance between the first electrode 2 and the second electrode 4. This is because, in the off state, an interface region 3a with a high oxygen content is formed by anodic oxidation in the variable resistance elements 3 at the interface between the second electrode 4 and the variable resistance elements 3.

For example, as shown in FIG. 2B, with the first electrode 2 as the cathode and the second electrode 4 as the anode, a voltage is applied between the first electrode 2 and the second electrode 4. In doing so, an electric field is generated between the first electrode 2 and the second electrode 4. The oxygen in the variable resistance elements 3 is ionized by this electric field. Then, the negative oxygen ions will move toward the second electrode 4 as the anode. The movement of the oxygen ions is carried out by the electric field.

The oxygen ions move from regions of high oxygen concentration to portions in which the oxygen is depleted. The oxygen ions may be supplied from one or both of the variable resistance elements 3 and the first separation section 5.

If the resistance of the variable resistance elements 3 is increased by the selection of the material, the movement of the oxygen ions due to the electric field is facilitated. When the oxygen ions are moved by the electric field, low electric power consumption can be achieved in the memory cell 1.

By allowing the flow of the electric current between the first electrode 2 and the second electrode 4, heat is generated inside the variable resistance elements 3. Because of this heat, the oxygen ions moving toward the second electrode 4 easily combine with the hole position formed by the oxygen content of the variable resistance elements 3 at or near the second electrode 4.

After this, the electrons of the oxygen ions are discharged into the second electrode 4. Migration of oxygen into the interface region 3a creates a region near the second electrode 4 having an oxygen content in the interface region 3a that is greater than the oxygen content of the remainder of the variable resistance elements 3. By migrating oxygen to the vicinity on the second electrode 4 side, the interface region 3a with the oxygen content higher than the remainder variable resistance elements 3 is formed, and is at or near stoichiometry and thus an insulator.

For example, oxygen ions migrate from the variable resistance elements 3 to the interface region 3a facilitated by the electric field. Migration of the oxygen from the variable resistance elements 3 provides oxygen to the interface region 3a and provides an oxygen content in the interface region 3a that is at or near the stoichiometric ratio in comparison to the oxygen content of the remainder of the variable resistance elements 3. In other words, a portion of the variable resistance elements 3 that is not included in the interface region 3a has an oxygen content that is less than the stoichiometric ratio, which renders the oxygen content of the interface region 3a being higher than the oxygen content of the variable resistance elements 3. Since the oxygen ions in the variable resistance elements 3 have moved to the interface region 3a, the oxygen content of the variable resistance elements 3 is lower than the oxygen content of the interface region 3a after the interface region 3a has been formed. After formation of the interface region 3a, the oxygen content of the non-interface 3a portion of the variable resistance elements 3 is lower than that of the state shown in FIG. 2A.

When the interface region 3a is formed into an oxide having a composition that is at or near the stoichiometric ratio, the interface region 3a has a higher insulation characteristic than the variable resistance elements 3. Therefore, by the formation of the interface region 3a, the resistance between the first electrode 2 and the second electrode 4 shifts from the low resistance state as described in FIG. 2A (i.e., the on state) to the high resistance state (i.e., the off state).

Here, if the second electrode 4 as the anode is formed from a material with which oxygen more easily combines as compared to the material of the variable resistance elements 3, there is a possibility of oxidation of the second electrode 4 during the operation of the memory cell 1. In other words, there is a possibility of damage to the second electrode 4 during the operation of the memory cell 1.

Thus, the material of the second electrode 4 and the material of the variable resistance elements 3 should be chosen with considerations regarding the thermodynamic stability of the materials. In this case, a material in which oxygen is more easily reacted should be chosen for the formation of the interface region 3a in order to control oxidation reactions in the memory cell 1. In one aspect, the material in which oxygen is more easily reacted comprises a material having a larger absolute value of the standard Gibbs free energy of formation per oxygen atom of the oxide as compared to materials that are more thermodynamically stable.

Therefore, the material contained in the variable resistance elements 3 comprises an element such as a metal with a greater absolute value of the standard Gibbs free energy of formation per oxygen atom of the oxide than the element contained in the second electrode 4.

In doing so, the oxygen ions will move up to the interface between the second electrode 4 and the variable resistance elements 3. However, rather than the formation of the oxide with the element of the second electrode 4, the oxidation is formed in the variable resistance elements 3 near the second electrode 4 (i.e., in the interface region 3a). As the material of the second electrode 4 is more stable, the oxide formation can be controlled and maintained in the variable resistance elements 3, and the oxidation of the second electrode 4 can be suppressed.

To be described later, there are cases in which the first electrode 2 is the anode. Therefore, it is also acceptable that the element contained in the variable resistance elements 3 can be an element having a larger absolute value of the standard Gibbs free energy of formation per oxygen atom of the oxide than the element contained in the first electrode 2. In this manner, the oxygen ions can move to the interface between the first electrode 2 and the variable resistance elements 3, and the first electrode 2 is not oxidized. Therefore, the oxidation of the first electrode 2 can be suppressed.

The thickness dimension of the interface region 3a can be controlled according to the voltage applied between the first electrode 2 and the second electrode 4 or the electric current value between the first electrode 2 and the second electrode 4. For example, it is possible to increase the voltage or to increase the electric current in order to increase the thickness of the interface region 3a.

However, if the voltage is increased excessively, there is a possibility of destroying the interface region 3a. In this case, for example, if the voltage is applied so that the thickness of the interface region 3a is less than 3 nm (nanometer), the destruction of the interface region 3a can be suppressed.

FIG. 2C is a diagram to illustrate an example of shifting of the memory cell 1 from the off state to the on state.

As shown in FIG. 2C, with the first electrode 2 as the anode and the second electrode 4 as the cathode, a voltage is applied between the first electrode 2 and the second electrode 4. In doing so, an electric field is generated selectively in the interface region 3a in a high resistance state. The oxygen ions in the interface region 3a move to the side of the first electrode 2 as the anode. When the oxygen ions in the interface region 3a move into the variable resistance elements 3, the interface region 3a will dissipate, and the variable resistance elements 3 is reformed between the second electrode 4 and the first electrode 2. In other words, when the interface region 3a disappears, and the variable resistance elements 3 reverts from the off state shown in FIG. 2B to the on state shown in FIG. 2A.

In this manner, in the memory cell 1, it is possible to carry out repeatedly the formation of the interface region 3a and the dissipation of the interface region 3a by the voltage control utilizing reversion of polarity. Therefore, in the memory cell 1, it is possible to form repeatedly the low resistance state and the high resistance state by repeatedly changing polarity. In doing so, the writing of data in the memory cell 1 or the erasing of data from the memory cell 1 is possible.

As described above, since the variable resistance elements 3 are formed from an oxide having an oxygen content that is less than the stoichiometric ratio, the electric current of the specified electric current value can flow between the electrodes 2 and 4.

Additionally, where a different voltage or a potential of a different polarity is applied to adjacent second electrodes 4, there is a possibility of a leaking electric current accompanying such a potential difference. However, the first separation section 5 between the adjacent variable resistance layers 3 prevents the leakage of electric current. This is an improvement over prior art devices.

FIG. 3 is a schematic cross-sectional diagram showing a comparative example of a prior art memory cell 51.

As shown in FIG. 3, the memory cell 51 related to the comparative example is provided with the first electrode 2, the resistance changing section 53, and the second electrodes 4. However, the first separation section 5 described previously is not provided, and the resistance changing section 53 as a film layer is provided.

In such a case, with one second electrode 4 as the anode and the second electrode 4 adjacent to it as the cathode, there is a possibility of electric current 52 leakage between the adjacent memory cells 51. If such a leaking electric current 52 flows, it will be recognized as an error rendering the write or erase operation ineffective.

In contrast to this, in the nonvolatile memory device 100 related to the embodiments described herein, the first separation section 5 is provided between the adjacent memory cells 1 to prevent the leakage.

Therefore, as shown in FIG. 2B, even with one second electrode 4 as the anode and the second electrode 4 adjacent to it as the cathode, the flowing of the leaking electric current between the adjacent memory cells 1 is suppressed. Therefore, the errors in the memory cells 1 can be suppressed.

The first separation section 5 has a higher oxygen content than the variable resistance elements 3. As shown in FIG. 2B, when the second electrode 4 is the anode, the first separation section 5 can also be a source for the supply of oxygen ions to the interface region 3a. Therefore, the formation of the interface region 3a can be facilitated, and the thickness of the interface region 3a can be increased.

As a result, the ratio of the electric current flowing in the high resistance state to the electric current flowing in the low resistance state can be increased, and the operation (i.e., the memory function) of the memory cell 1 can be made reliable.

The variable resistance elements 3 and the first separation section 5 provided on plural memory cells 1 are made into one body and comprise a film layer. The first separation section 5 can comprise an oxide compound having the same constituent elements as the oxide compound contained in the variable resistance elements 3. Therefore, a cost reduction and an improvement in mass production in the manufacture of the nonvolatile memory devices 100 having plural memory cells 1 can be achieved. The details in regard to the manufacture of the nonvolatile memory devices 100 will be described later.

### Embodiment 2

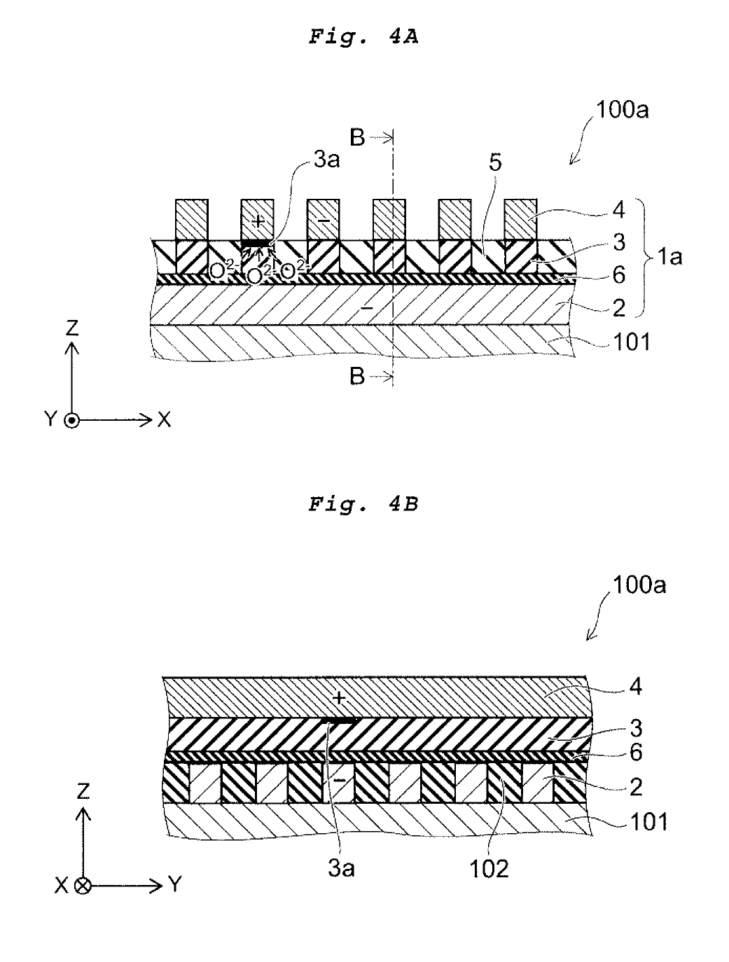

FIGS. 4A and 45 are schematic cross-sectional diagrams showing a memory cell 1a of a nonvolatile memory device 100a according to the second embodiment. FIG. 4B is the cross-sectional diagram of the section B-B in FIG. 4A.

As shown in FIGS. 4A and 4B, the memory cell 1a is provided with the first electrode 2, the variable resistance elements 3, the second electrode 4, and a second separation section 6.

The first separation section 5 is provided between the variable resistance layers 3 of the adjacent memory cells 1a.

The second separation section 6 comprises a film layer, and is provided between the first electrode 2 layer and the layer comprising the variable resistance elements 3, as in the prior embodiment and the first separation section 5.

The second separation section 6 has a specified insulation characteristic.

As shown in FIG. 1A described previously, by the provision of the first separation section 5, the leakage of electric current between the adjacent memory cells 1 in the X direction can be suppressed.

However, as shown in FIG. 1B, since the first separation section 5 is not provided between the adjacent memory cells 1 in the Y direction, it is difficult to suppress the leakage of electric current between the adjacent memory cells 1 in the Y direction.

In this embodiment, since the second separation section 6 is provided, the leakage of electric current flowing between the first electrodes 2 can be suppressed.

The material of the second separation section 6 can comprise an element with a larger absolute value of the standard Gibbs free energy of formation per oxygen atom of the oxide than the element contained in the variable resistance elements 3.

In this case, the second separation section 6 can be an oxide material.

The absolute value of the standard Gibbs free energy of formation per oxygen atom in the case of changing the element contained in the second separation section 6 section into oxide can be larger than the absolute value of the standard Gibbs free energy of formation per oxygen atom in the case of changing the element contained in the variable resistance elements 3 into an oxide, and thus the oxygen ions moving within the variable resistance elements 3 will not react with the element of the oxide in the separation layer 6.

In doing so, the reduction of the second separation layer 6 during the operation of the memory cell 1 can be suppressed. In other words, the damage of the second separation section 6 during the action of the memory cell 1 can be suppressed.

In the case of the formation of the second separation section 6 from the oxide, it can be such that the second separation section 6 comprises an oxide having an oxygen content that is at or near the stoichiometric ratio. In doing so, the reduction of the variable resistance elements 3 during the operation of the memory cell 1 can be suppressed.

The resistance of the second separation section 6 can be increased further to provide additional insulative characteristics.

The band gap of the second separation section 6 may be greater than the band gap of the variable resistance elements 3, and the dielectric constant of the second separation section 6 can be less than the dielectric constant of the variable resistance elements 3.

Thus, it is possible that the second separation section 6 may also function as a rectifier.

In order to have a band gap of the second separation section 6 greater than the band gap of the variable resistance elements 3, and a dielectric constant of the second separation section 6 less than the dielectric constant of the variable resistance elements 3, for example, the second separation section 6 can be formed from SiO₂ or the like. Alternatively, a gap, a void, or the like, may be provided inside the variable resistance elements 3 in the vicinity of the first electrode 2, and the portion provided with the gap, the void, or the like of the variable resistance elements 3 may this form a second separation section.

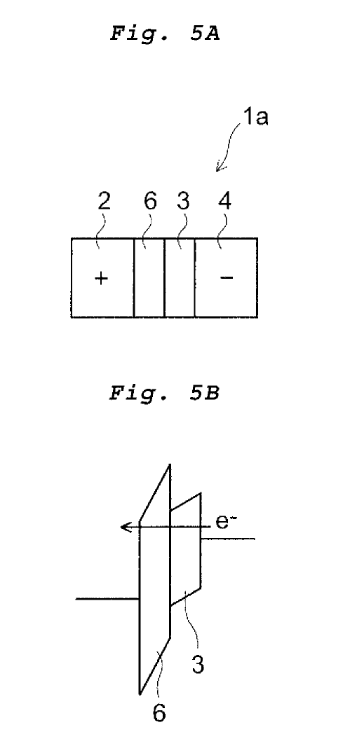

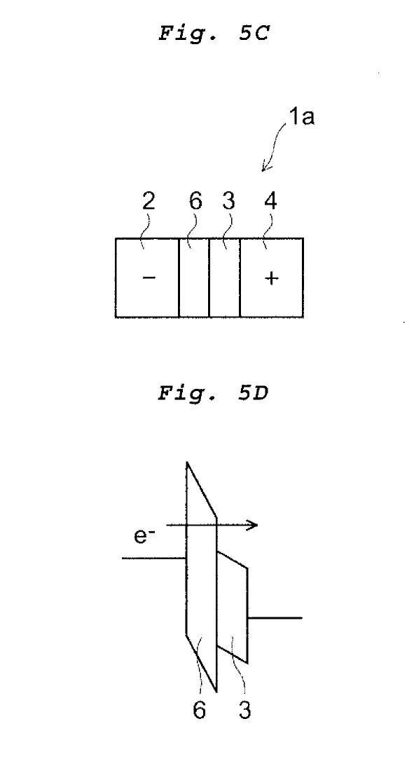

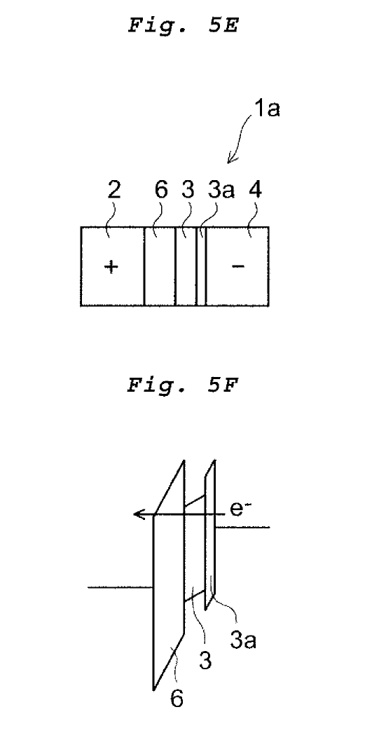

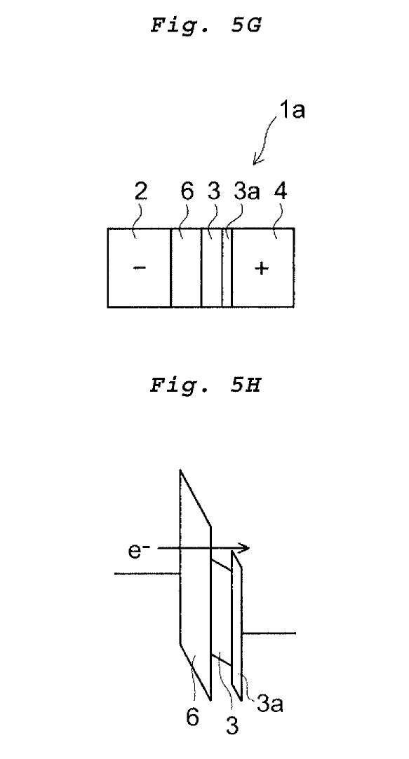

FIGS. 5A to 5H are schematic diagrams showing the rectification characteristics of the second separation section 6.

FIGS. 5A to 5D represent the manner of shifting of the memory cell 1a from the on state to the off state. FIGS. 5A and 5B are the case of application of voltage of a first polarity (i.e., reverse polarity), and FIGS. 5C and 5D are the case of the application of the voltage of a second polarity (i.e., normal polarity).

FIGS. 5E to 5H represent the operation during the shifting of the memory cell 1a from the off state to the on state. FIGS. 5E and 5F are the case of application of reverse polarity voltage, and FIGS. 5G and 5H are the case of application of the normal polarity voltage.

FIGS. 5A, 5C, 5E and 5G represent the constitution of the memory cell 1a in various states, and FIGS. 5B, 5D, 5F and 5H represent the energy band structure in various states.

In the case of application of the voltage in the normal direction, as shown in FIG. 5D, it is acceptable that the electrons e− pass through the second separation section 6. Therefore, the electric current in the normal direction flows easily through the memory cell 1a.

On the other hand, in the case of the application of the voltage in the reverse direction, as shown in FIG. 5B, the electrons e− have to pass through the variable resistance elements 3 and the second separation section 6. Therefore, the flow of electric current in the reverse direction is difficult.

As shown in FIGS. 5E and 5G, during the shifting of the memory cell 1a from the off state to the on state, the interface region 3a is formed.

Therefore, in the case of the application of the voltage in the direction shown in FIG. 5H, it is acceptable that the electrons e− pass through the second separation section 6. Therefore, the electric current in the normal direction flows easily.

On the other hand, in the case of the application of the voltage in the reverse direction, as shown in FIG. 5F, the electrons e− have to pass through the interface region 3a, the variable resistance elements 3 and the second separation section 6. Therefore, the flow of electric current in the reverse direction is difficult.

The energy band structure exemplified in FIGS. 5B, 5D, 5F and 5H can be formed by having the band gap of the second separation section 6 being greater than the band gap of the variable resistance elements 3, and having the dielectric constant of the second separation section 6 less than the dielectric constant of the variable resistance elements 3.

In other words, by having the band gap of the second separation section 6 larger than the band gap of the variable resistance elements 3, and having the dielectric constant of the second separation section 6 lower than the dielectric constant of the variable resistance elements 3, rectification characteristics can be provided by the second separation section 6.

Here, with the second separation section 6 as a single layer, the addition of rectification characteristics to the second separation section 6 by the band gap and dielectric differences relative to the variable resistance elements 3 has been explained. However, it is also acceptable to provide rectification characteristics by the second separation section 6 alone by forming the second separation section 6 from two or more layers having different band gaps and dielectric constants.

When the interface region 3a is dissipated by the application of the voltage with the second electrode 4 as the cathode, (i.e., shifting from the off state to the on state), there is also a possibility of the formation of the interface region 3a at the interface between the first electrode 2 as the anode and the variable resistance elements 3. In other words, even if the interface region 3a is not formed at the interface between the second electrode 4 and the variable resistance elements 3, there is a possibility of the formation of a new interface region 3a at the interface between the first electrode 2 and the variable resistance elements 3. If the new interface region 3a is formed at the interface between the first electrode 2 and the variable resistance elements 3, it will be difficult for the memory cell 1a to return to the low resistance state.

In this case, if rectification characteristics can be added to the second separation section 6, in the case of shifting from the off state to the on state, the formation of the new interface region 3a at the interface between the first electrode 2 and the variable resistance elements 3 can be suppressed since the movement of electrons e− to the first electrode 2 side will be difficult. Therefore, it is possible to perform the shifting from the off state to the on state in a reliable manner.

If rectification characteristics can be added to the second separation section 6, the reverse flow of the electric current can be suppressed, even in the case of having a potential difference between plural memory cells 1a connected to the linear first electrode 2 or the linear second electrode 4 (i.e., the bit line or the word line). Therefore, the number of the memory cells 1a that can be connected to the linear first electrode 2 or the linear second electrode 4 can be increased. In other words, the nonvolatile memory device 100a can be further increased in capacity.

Without the formation of the second separation section 6 having the rectification characteristics, other rectifying devices, such as a silicon diode, may need to be provided to the memory cell 1a. However, the process for the forming of the rectifying devices may cause a large increase in the manufacturing cost of the memory cell 1a.

In contrast to this, in the provision of the second separation section 6, it is acceptable to form the second separation section 6 as a film layer within the memory cell 1a. Therefore, a cost reduction and/or an improvement in mass production of the nonvolatile memory devices 100a can be achieved.

### Embodiment 3

Next, an example will be given in regard to the method for the manufacture of the nonvolatile memory devices 100, 100a.

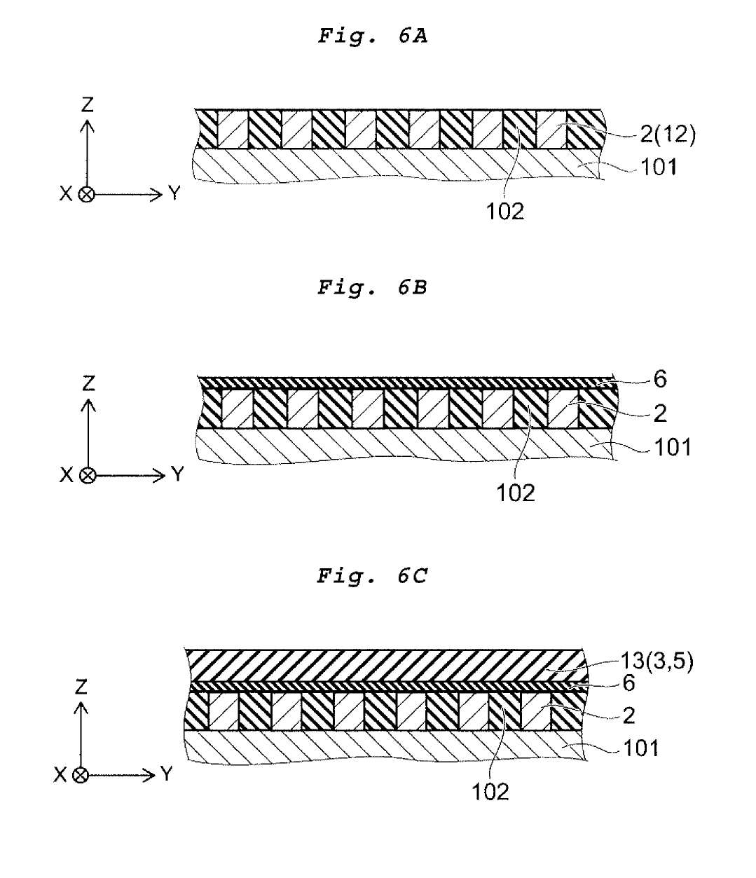

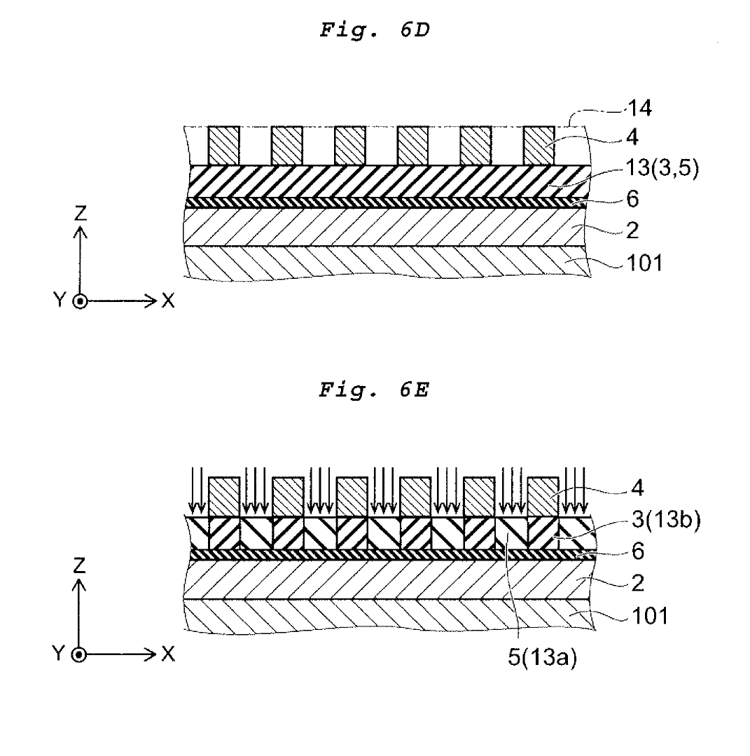

FIGS. 6A to 6E are schematic cross-sectional diagrams for explanation of the method for the manufacture of the nonvolatile memory devices 100, 100a.

First of all, as shown in FIG. 6A, for example, a deposition process such as a sputtering method or the like is used for the formation of a first film 12 as the first electrode 2 on top of a substrate 101 containing silicon.

The first film 12 as the first electrode 2 can be formed from, for example, W, TiN, TaN or the like.

Then, a photolithographic method and the RIE method or the like are used for the plural formation of the first electrode 2 having a specified shape in the first film 12.

CVD (Chemical Vapor Deposition) or the like is used for the formation of a film including SiO₂ so that the first electrode 2 is coated and the spaces between the first electrodes 102 is filled with an insulator. A CMP (Chemical Mechanical Polishing) method or the like is used for flattening the film until the first electrode 2 is exposed. At this time, the insulation section 102 formed of SiO₂ or the like remains between the first electrodes 2.

Next, as shown in FIG. 6P, in the case of the provision of the second separation section 6, for example, a CVD method or the like is used for the formation of the second separation section 6 on top of the first electrodes 2. The second separation section 6 can be formed from, for example, SiO₂ or the like.

Next, an example will be given in regard to the case of the provision of the second separation section 6 in the following. However, it is possible to have the same as in the case without the provision of the second separation section 6 as described in the memory cell 1 of the nonvolatile memory device 100 (shown in FIGS. 1-2C).

Next, as shown in FIG. 6C, for example, the sputtering method, the CVD method, an ALD (Atomic Layer Deposition) method or the like is used for the formation of a second film 13 (equivalent to an example of the first film) including the variable resistance elements 3 and the first separation section 5 on top of the second separation section 6. In the case where the second separation section 6 is not formed, the second film 13, which includes the variable resistance elements 3 and the first separation section 5, is formed on top of the plural first electrodes 2 as well as the insulating section 102.

The second film 13 including the variable resistance elements 3 and the first separation section 5 can be formed from an oxide having an oxygen content that is less than the stoichiometric ratio (for example, NbOₓ (where x is less than 2.5) or the like, in a state where holes where the layer is electron depleted is formed.

In the case of using the sputtering method, it is possible that oxygen is introduced into the reaction chamber, and the specified metal target is sputtered to form the second film 13 as the oxide film.

In the case of using the CVD method or the ALD method, a raw material gas is introduced into the reaction chamber to form the metal film and, by the heat treatment of the metal film formed in an atmosphere containing oxygen, the second film 13 as the oxide film can be formed.

By the control of the oxygen amount during the formation of the second film 13, the oxide with an oxygen content that is less than the stoichiometric ratio may be formed.

Here, the second film 13 and the second separation section 6 can be the materials containing oxide.

The absolute value of the standard Gibbs free energy of formation per oxygen atom in the case of changing the element contained in the second separation section 6 into oxide can be larger than the absolute value of the standard Gibbs free energy of formation per oxygen atom in the case of changing the element contained in the second film 13 into oxide.

The band gap of the second separation section 6 is greater than the band gap of the second film 13, and the dielectric constant of the second separation section 6 is less than the dielectric constant of the second film 13.

Next, as shown in FIG. 6D, for example, the sputtering method or the like is used for the formation of the third film 14 as the second electrode 4 on top of the second film 13 including the variable resistance elements 3 and the first separation section 5.

The third film 14 as the second electrode 4 can be formed from, for example, Ru or the like.

Here, the material of the variable resistance elements 3 and the second electrode 4 is a combination that can satisfy the magnitude relationship of the absolute values of the standard Gibbs free energy of formation described above. Since the details in regard to the material of the variable resistance elements 3 and the second electrode 4 can be the same as those described above, the explanation will be omitted.

Then, the photolithographic method and the RIE method or the like are used for the plural formation of the second electrode 4 having the specified shape within the third film 14.

Next, on the second film 13, the variable resistance elements 3 and the first separation section 5 are formed.

For example, as shown in FIG. 6E, by increasing the oxygen content of the portion 13a exposed between the second electrodes 4 of the second film 13, the first separation section 5 is formed. Methods for increasing the oxygen content of the portion 13a include the injection of oxygen ions into the second film 13 by using oxygen ion implantation methods or the oxidation of the second film 13 by thermal oxidation methods, plasma oxidation methods or the like can be used. At this time, the portion 13b is masked by the second electrode 4 from ions or oxidizing gas and retains an oxygen content as described in FIG. 6C.

There are no special restrictions in the oxygen content during the formation of the first separation section 5. The oxygen content is acceptable as long as the oxygen content of the oxide contained in the first separation section 5 is higher than the oxygen content of the oxide contained in the variable resistance elements 3.

In this case, it is also possible that the oxygen content of the oxide contained in the first separation section 5 is one having the composition ratio at or near the stoichiometric ratio.

According to the embodiments, during the formation of the variable resistance elements 3 and the first separation section 5, without performing bulk etch processing, plural variable resistance layers 3 and the first separation section 5 can be formed.

Therefore, the method for the manufacture of the nonvolatile memory devices that are low in cost and amenable to mass production can be accomplished.

Without the formation of a silicon diode or other rectifying devices, rectification characteristics can be obtained by the formation of the second separation section 6 in a film layer.

While certain embodiments have been described, these embodiments have been presented by way of example only, and are not intended to limit the scope of the inventions. Indeed, the novel embodiments described herein may be embodied in a variety of other forms; various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile memory device, comprising:
a first film layer formed on a substrate;
a second film layer formed on the first film layer, the second film layer comprising:
a first oxide material having a first oxygen content; and
a second oxide material disposed laterally of the first oxide material and having a second oxygen content that is greater than the first oxygen content; and
a third film layer formed on the second film layer, the third film layer disposed on the first oxide material and exposing portions of the second oxide material.

2. The nonvolatile memory device of claim 1, wherein, in the presence of an electric field, the first oxygen content in a portion of the first oxide material is substantially equal to a stoichiometric amount of oxygen.

3. The nonvolatile memory device of claim 1, wherein the first oxide material and the second oxide material comprise the same constituent elements.

4. The nonvolatile memory device of claim 1, wherein the first film layer comprises a plurality of linear, repeating rows of a conductive material disposed in a first direction on the substrate and a plurality of insulating sections disposed between the rows.

5. The nonvolatile memory device of claim 4, wherein second oxide material comprises a plurality of linear, repeating rows disposed in a second direction on the first film layer, the second direction being substantially normal to the first direction.

6. The nonvolatile memory device of claim 5, wherein the third film layer comprises a plurality of linear, repeating rows disposed in the second direction on the second film layer.

7. The nonvolatile memory device of claim 1, further comprising:
a separation layer disposed between the first film and the second film.

8. The nonvolatile memory device of claim 7, wherein the separation layer comprises an oxide material having an oxygen content greater than the first oxygen content.

9. The nonvolatile memory device of claim 7, wherein the first oxide material comprises a material having a first band gap and the separation layer comprises a material having a second band gap that is greater than the first band gap.

10. The nonvolatile memory device of claim 7, wherein the first oxide material comprises a material having a first dielectric constant and the separation layer comprises a material having a second dielectric constant that is less than the first dielectric constant.

11. A nonvolatile memory device, comprising:
a plurality of memory cells, each of the plurality of memory cells comprising:
a first electrode;
a variable resistance layer disposed on the first electrode, the variable resistance layer comprising a first oxide material having a first oxygen content; and
an insulative region disposed adjacent the variable resistance layer, wherein the insulative region comprises a second oxide material having a second oxygen content that is greater than the first oxygen content; and
a second electrode disposed on the variable resistance layer.

12. The nonvolatile memory device of claim 11, wherein the first oxide material and the second oxide material comprise the same constituent elements.

13. The nonvolatile memory device of claim 11, wherein, in the presence of an electric field, the first oxygen content is substantially equal to a stoichiometric amount of oxygen.

14. The nonvolatile memory device of claim 11, further comprising:
a separation layer disposed between the variable resistance layer and the second electrode.

15. The nonvolatile memory device of claim 14, wherein the separation layer comprises an oxide material having an oxygen content greater than the first oxygen content.

16. The nonvolatile memory device of claim 14, wherein the first oxide material comprises a material having a first band gap and the separation layer comprises a material having a second band gap that is greater than the first band gap.

17. The nonvolatile memory device of claim 14, wherein the first oxide material comprises a material having a first dielectric constant and the separation layer comprises a material having a second dielectric constant that is less than the first dielectric constant.

18. A method for manufacturing a nonvolatile memory device, the method comprising:
forming a first film layer on a substrate;
forming a second film layer on the first film layer, the second film layer comprising:
a first oxide material having a first oxygen content; and
a second oxide material disposed laterally of the first oxide material and having a second oxygen content that is greater than the first oxygen content; and
forming a third film layer on the second film layer, the third film layer disposed on the first oxide material and exposing portions of the second oxide material.

19. The method of claim 18, wherein, in the presence of an electric field, the first oxygen content is substantially equal to a stoichiometric amount of oxygen.

20. The method of claim 18, wherein the first oxide material and the second oxide material comprise the same constituent elements.
